(19) United States
(12) Patent Application Publication
(10) Pub. No.: US 2019/0326893 A1
(43) Pub. Date: Oct. 24, 2019

(54) SEMICONDUCTOR INTEGRATED CIRCUIT DEVICE INCLUDING A DELAY CIRCUIT

(71) Applicant: SK hynix Inc., Icheon-si Gyeonggi-do (KR)

(72) Inventors: Hyun Bo CHO, Seoul (KR); Young Dal ROH, Icheon-si Gyeonggi-do (KR)

(73) Assignee: SK hynix Inc., Icheon-si Gyeonggi-do (KR)

(21) Appl. No.: 16/155,352

(22) Filed: Oct. 9, 2018

(30) Foreign Application Priority Data
Apr. 23, 2018 (KR) 10-2018-0046578

(51) Int. Cl. H03K 5/134

(52) U.S. Cl. CPC H03K 5/134; H03K 2005/00058

(57) ABSTRACT

A semiconductor integrated circuit device may include first and second delay circuits and a control circuit block connected between the first and second delay circuits. The first and second delay circuits may each include a plurality of delay elements serially connected with each other. The control circuit block may receive an output signal of the first delay circuit. The control circuit block may input an inversion signal, which may be generated by inverting the output signal of the first delay circuit, into the second delay circuit in response to a compensation signal.

### CROSS-REFERENCES TO RELATED APPLICATION

The present application claims priority under 35 U.S.C. § 119(a) to Korean application number 10-2018-0046578, filed on Apr. 23, 2018, in the Korean Intellectual Property Office, which is incorporated herein by reference in its entirety.

### BACKGROUND

### 1. Technical Field

Various embodiments may generally relate to a semiconductor integrated circuit device, and more particularly, to a semiconductor integrated circuit device including a delay circuit.

### 2. Related Art

A plurality of semiconductor devices may require a delay circuit for properly transmitting signals. The delay circuit may include an inverter chain or a NAND logic chain.

Each of a CMOS inverter and a NAND logic may include an NMOS transistor and a PMOS transistor. When a stress application process such as a burn-in test is performed on the NMOS transistor and the PMOS transistor, a negative bias temperature instability (NBTI) may be generated to deteriorate a threshold voltage and a driving current of the transistors. An NBTI is a reliability issue in MOSFETs. An NBTI results in an increase in the threshold voltage and consequent decrease in drain current and transconductance of a MOSFET. The degradation has logarithmic dependence on time. It generally affects p-channel MOS devices, since they almost always operate with negative gate-to-source voltage. However, an NBTI can also affect NMOS transistors when biased in the accumulation regime, i.e., with a negative bias applied to the gate.

The NBTI may increase the threshold voltage of the PMOS transistor and hinder a formation of a channel in the PMOS transistor due to stresses when the PMOS transistor is maintained in a turned-on state. That is, when the PMOS transistor is exposed to the NBTI, an operational timing of the PMOS transistor may be changed. Thus, a duty ratio distortion of the delay circuit may be generated.

### SUMMARY

In example embodiments of the present disclosure, a semiconductor integrated circuit device may include first and second delay circuits and a control circuit block connected between the first and second delay circuits. The first and second delay circuits may each include a plurality of delay elements serially connected with each other. The control circuit block may receive an output signal of the first delay circuit. The control circuit block may input an inversion signal, which may be generated by inverting the output signal of the first delay circuit, into the second delay circuit in response to a compensation signal.

In example embodiments of the present disclosure, a semiconductor integrated circuit device may include a plurality of unit delay lines. Each of the unit delay lines may include a plurality of delay elements serially connected with each other. A first portion of the unit delay lines may be operated in a delay operating mode and a remaining portion of the unit delay lines may be operated in a standby mode based on a control signal. Odd delay elements among the plurality of delay elements of the unit delay lines in the standby mode receive an input signal having a level contrary to a level of an input signal inputted into odd delay elements among the delay elements of the plurality of unit delay lines in the delay operating mode.

### BRIEF DESCRIPTION OF THE DRAWINGS

The accompanying figures, where like reference numerals refer to identical or functionally similar elements throughout the separate views, together with the detailed description below, are incorporated in and form part of the specification, and serve to further illustrate embodiments of concepts that include the claimed novelty, and explain various principles and advantages of those embodiments.

FIG. 1 illustrates a semiconductor integrated circuit device, in accordance with example embodiments.

FIG. 2 shows a circuit diagram illustrating a delay circuit block, in accordance with example embodiments.

FIG. 3 shows a circuit diagram illustrating a control circuit block, in accordance with example embodiments.

FIG. 4 illustrates an inverter, in accordance with example embodiments.

FIG. 5 shows a timing chart illustrating a duty ratio transition of an inverter, in accordance with NBTI.

FIG. 6 illustrates compensation processes of a duty distortion of a delay circuit block, in accordance with example embodiments.

FIG. 7 shows a graph illustrating a duty ratio transition, in accordance with example embodiments.

FIG. 8 shows a block diagram illustrating a delay circuit block, in accordance with example embodiments.

FIG. 9 shows a circuit diagram illustrating a unit delay line in FIG. 8.

FIG. 10 shows a block diagram illustrating various operations of a plurality of unit delay lines, in accordance with example embodiments.

FIG. 11 shows a table illustrating application conditions of path control signals for operating unit delay lines and signal levels of input/output nodes, in accordance with the application conditions.

### DETAILED DESCRIPTION

Various embodiments of the present invention are described in detail with reference to the accompanying drawings. The drawings represent schematic illustrations of various embodiments (and intermediate structures). As such, variations from the configurations and shapes of the illustrations as a result, for example, of manufacturing techniques and/or tolerances, are to be expected. Thus, the described embodiments should not be construed as being limiting with respect to the particular configurations and shapes illustrated herein. Instead, deviations in configuration and/or shape from present embodiments are possible which do not depart from the spirit and scope of the appended claims.

The present disclosure references cross-section and/or plan illustrations of idealized embodiments. However, these embodiments should not be construed as limiting the present disclose. Although a limited number of embodiments are presented, it will be appreciated by those of ordinary skill in the art that changes may be made to these embodiments without departing from the principles and spirit of the present disclosure as set forth in the claims below.

Example embodiments may provide a semiconductor integrated circuit device capable of improving characteristics of an output signal of a delay circuit.

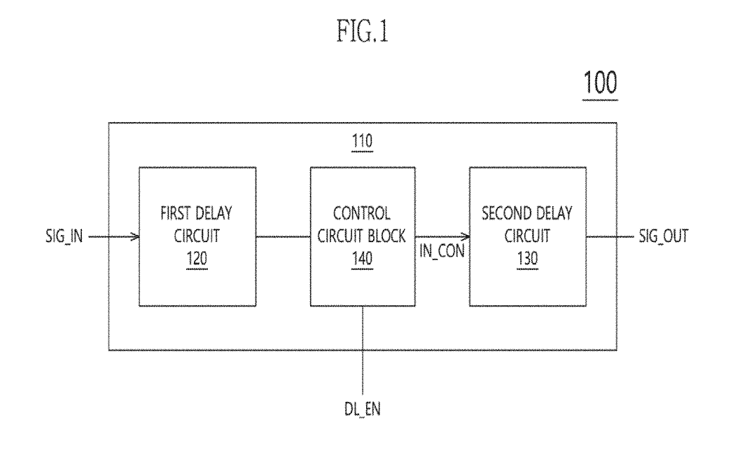

FIG. 1 shows a view illustrating a semiconductor integrated circuit device 100 in accordance with example embodiments.

Referring to FIG. 1, the semiconductor integrated circuit device 100 may include a delay circuit block 110. The delay circuit block 110 may include a first delay circuit 120, a second delay circuit 130, and a control circuit block 140.

The first delay circuit 120 and the second delay circuit 130 may be divided to include corresponding numbers of delay elements. The first delay circuit 120, for instance, includes a first plurality of delay elements, and the second delay circuit 130 includes a second plurality of delay elements. The first and second delay circuits 120 and 130 may include the delay elements serially connected with each other. For example, the first and second delay circuits 120 and 130 may have substantially the same configuration. Further, the delay elements may be configured to perform a NAND operation or perform an inversion operation. In some embodiments, the delay elements may include an inverter or a NAND gate (also referred to a NAND logic gate). For example, when an input delay path and an output delay path represent an anti-parallel delay circuit block, the input delay path may correspond to the first delay circuit 120 and the output delay path may correspond to the second delay circuit 130. In some embodiments, the output delay path being anti-parallel to the input delay path means the direction of signal propagation for the output delay path is opposite to the direction of signal propagation for the input delay path.

The control circuit block 140 may be connected between the first delay circuit 120 and the second delay circuit 130. The control circuit block 140 may change a level of an input signal of the second delay circuit 130 in response to a compensation signal DL_EN. For example, the compensation signal DL_EN may be provided from a controller (not shown). The compensation signal DL_EN may be a signal for determining the start of a standby mode, after a burn-in test of the semiconductor integrated circuit device is completed. A delay operating mode may be changed depending on a level of the compensation signal DL_EN. The delay operating mode may include the burn-in test mode and a standby operating mode.

The control circuit block 140 may transmit an output signal of the first delay circuit 120 to the second delay circuit 130. Alternately, the control circuit block 140 may invert the output signal of the first delay circuit 120 and then transmit the inverted output signal to the second delay circuit 130, in response to the compensation signal DL_EN.

The delay elements in the first delay circuit 120 and the delay elements in the second delay circuit 130 may be repeatedly operated to incur an NBTI in an operation mode such as a burn-in test mode and a delaying operation mode.

When the compensation signal DL_EN is enabled, an input signal of the second delay circuit 130 may be changed by a driving of the control circuit 140. Thus, a part of delay elements in the second delay circuit 130 get stress by NBTI. The part of delay elements that were not stressed by NBTI when the compensation signal DL_EN is not enabled, may get stress according to a change of the input signal of the second delay 130. Therefore, an output pulse of the second delay circuit 130 may be changed to compensate a duty ratio.

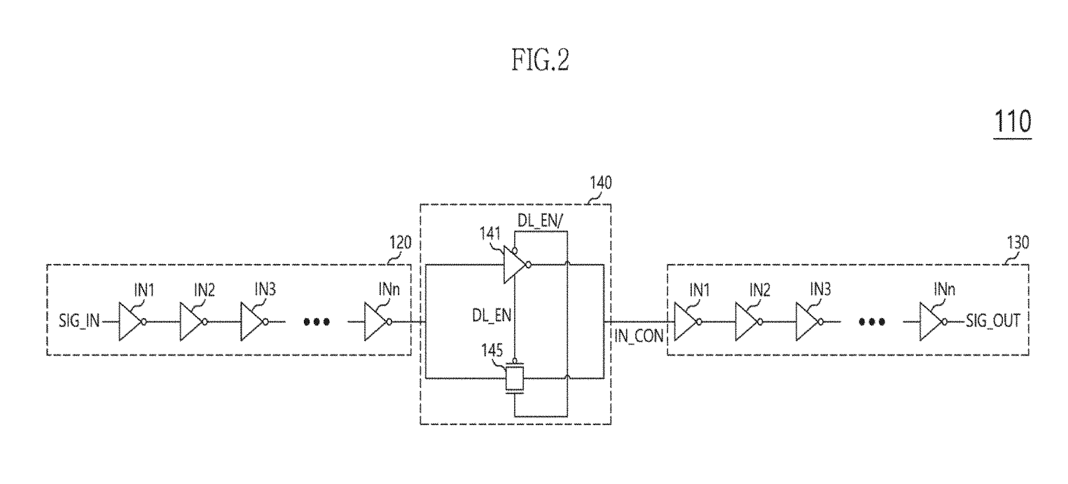

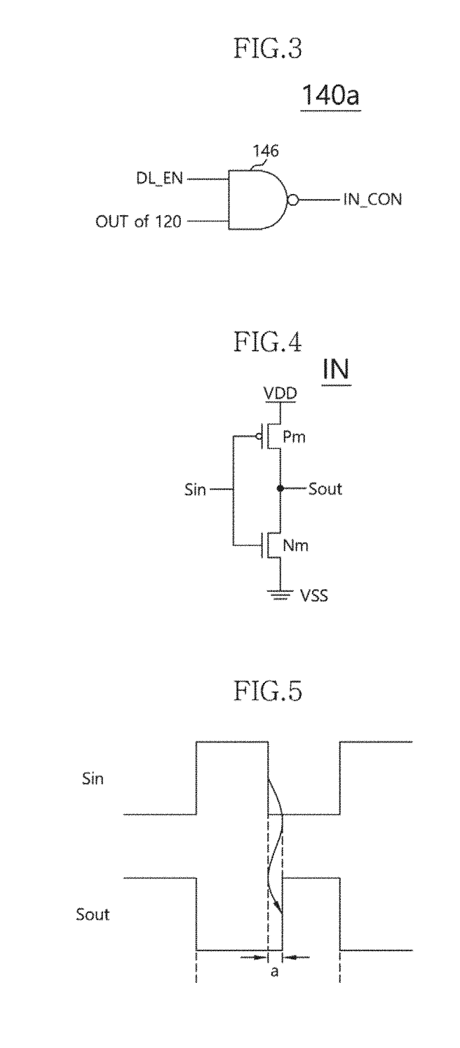

FIG. 2 shows a circuit diagram illustrating a delay circuit block 110 in accordance with example embodiments, and FIG. 3 shows a circuit diagram illustrating a control circuit block in accordance with example embodiments.

Referring to FIG. 2, the first delay circuit 120 of the delay circuit block 110 may include n inverters IN1˜INn connected in series. As used herein, the tilde “˜” indicates a range of components. For example, “IN1˜INn” indicates the inverters IN1, IN2, and INn shown in FIG. 2. The first delay circuit 120 may receive an input signal SIG_IN. The inverters IN1˜INn of the first delay circuit 120 may sequentially perform inverting operations.

The second delay circuit 130 may include n inverters IN1˜INn connected in series. The inverters IN1˜INn of the second delay circuit 130 may be symmetrical to the inverters IN1˜INn of the first delay circuit 120.

The control circuit block 140 may include an inverter 141 and a transmission unit 145. In order to compensate the duty ratio, when the compensation signal DL_EN is enabled to a high level, the inverter 141 may invert the output signal of the first delay circuit 120 and then output the inverted signal as an input control signal IN_CON. As used herein, a signal, such the compensation signal DL_EN or a path control signal, having a low level distinguishes from the signal when it has a high level. For example, the high level may correspond to the signal having a first voltage, and the low level may correspond to the signal having a second voltage. For some embodiments, the first voltage is greater than the second voltage. In other embodiments, different characteristics of a signal, such as frequency or amplitude, determine whether the signal has a high level or a low level. For some cases, the high and low levels of a signal represent logical binary states.

When the compensation signal DL_EN is disabled to a low level, the transmission unit 145 may provide the output signal of the first delay circuit 120 as the input control signal IN_CON. For example, the inverter 141 may include a three phase inverter and the transmission unit 145 may include a transfer gate. When the delay circuit block 110 is in an operation mode, such as the burn-in test mode, the compensation signal DL_EN may be disabled. In contrast, when the delay circuit block 110 is in a standby mode, the compensation signal DL_EN may be enabled.

The control circuit block 140 might not be restricted within the structure in FIG. 2. Referring to FIG. 3, the control circuit block 140 may include a NAND gate 146 for receiving the output signal of is the first delay circuit 120 and the compensation signal DL_EN.

Referring to FIG. 2, the second delay circuit 130 may receive the input control signal IN_CON to drive the inverters IN1˜INn of the second delay circuit 130.

For example, when the compensation signal DL_EN is disabled (for example, a burn-in test mode), the first and second delay circuits 120 and 130 may each receive a signal with a low level, the input signals SIG_IN and IN_CON, respectively. Then, the odd inverters IN1, IN3, etc. of the first and second delay circuits 120 and 130 may get the NBTI-influence, in common.

Meanwhile, when the compensation signal DL_EN is enabled (for example, a standby mode), the level of the input control signal IN_CON of the second delay circuit 130 may be inverted in accordance with the compensation signal DL_EN, unlike the input signal SIG_IN of the first delay circuit 130. Thus, the even inverters IN2, IN4, etc. of the second delay circuit 130 may get the NBTI-influence in common. Therefore, duty ratio distortion caused by the NBTI of the first and second delay circuits 120 and 130 may be offset.

FIG. 4 shows a view illustrating an inverter in accordance with embodiments, and FIG. 5 shows a timing chart illustrating a duty ratio transition of an inverter in accordance with NBTI.

Referring to FIG. 4, an inverter IN may include a PMOS transistor Pm and an NMOS transistor Nm. The PMOS transistor Pm may include a gate for receiving an input signal Sin, a source connected to a power voltage VDD, and a drain connected to the NMOS transistor Nm. The NMOS transistor Nm may include a gate for receiving an input signal Sin, a drain connected to the PMOS transistor Pm, and a source connected to a ground voltage VSS. The inverter IN may receive the input signal Sin. The inverter IN may invert the input signal Sin. The inverter IN may output the inverted signal as an output signal Sout.

As indicated above, when an inverting operation is processed for a long time, such as for a burn-in test, a threshold voltage and rising/falling timings of the PMOS transistor Pm in the inverter IN may be changed due to the NBTI.

As shown in FIG. 5, when the input signal Sin has a low level, the rising timing of the output signal Sout from the inverter IN may be delayed due to deteriorations of the PMOS transistor so that the duty ratio may be distorted. Particularly, when the inverters in the delay circuits 120 and 130 are connected in series, the distortions of the duty ratio may be accumulated so that the duty ratio distortion may greatly increase. In FIG. 5, a reference “a” may represent a delay of a rising edge due to the NBTI.

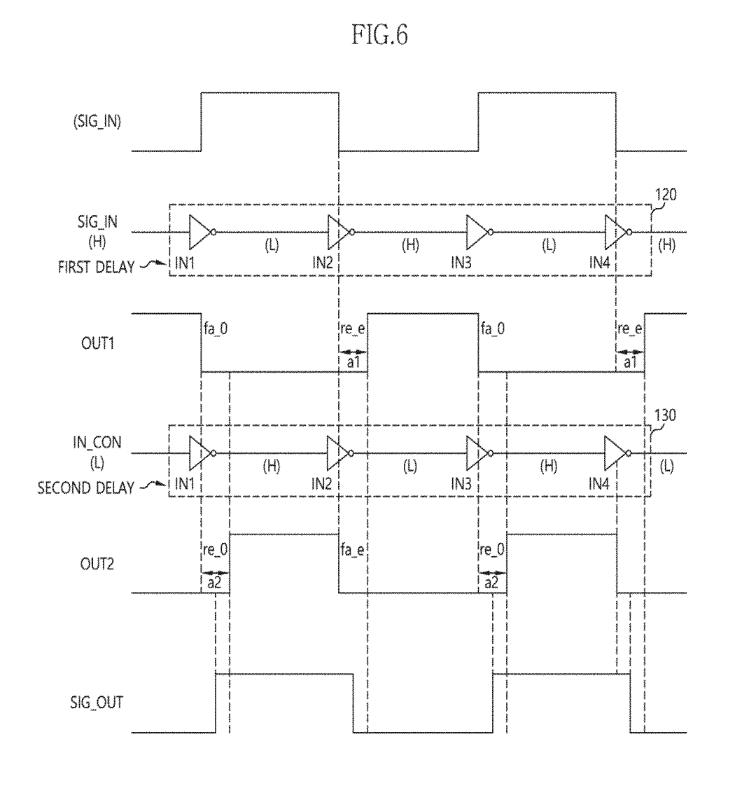

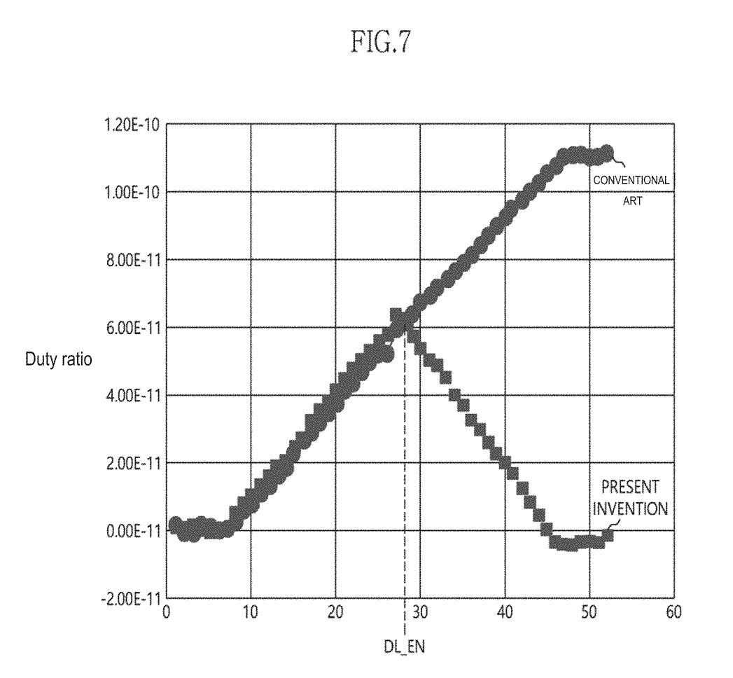

FIG. 6 shows a view illustrating compensation processes of a duty distortion of a delay circuit block in accordance with example embodiments. For convenience of explanation, the delay circuit block may include eight inverters. The first delay circuit 120 and the second delay circuit 130, indicated by broken lines, may each include four inverters among the eight inverters.

When a signal SIG_IN is continuously toggled by a burn-in test and a normally delay operations, the PMOS transistor in the even or odd inverters of the first and second delay circuits 120 and 130 may get the NBTI stress.

As shown in FIG. 6, when the first inverter IN1 of the first delay circuit 120 receives a high level signal H as the input signal SIG_IN of the first delay circuit 120, the even inverters IN2 and IN4 of the first delay circuit 120 may be affected by the NBTI. Here, output pulses OUT1 and OUT2 represent extreme output signals of each delay component of the first and second delay circuits 120 and 130 to aid in explanation of the compensation processes. According to the an output pulse OUT1, rising edges re_e of the even inverter IN2 and IN 4 are delayed by a time a1, due to the NBTI effect.

The compensation signal DL_EN may be enabled in the standby operation. The first inverter IN1 of the second delay circuit 130 might not receive the output signal of the first delay circuit 120, but may receive an inverted output signal of the first delay circuit 120.

The first inverter IN1 of the second delay circuit 130 may receive the input control signal IN_CON having a low level contrary to the first delay circuit 120. The odd inverters IN1 and IN3 of the second delay circuit 130 may receive the low level of the signal so that the odd inverters IN1 and IN3 of the second delay circuit 130 may be affected by the NBTI. According to the output pulse OUT2 of the second delay circuit 130, rising edges re_o of the odd inverters IN1 and IN3 are delayed by a time a2.

As a result, a duty ratio of a total output SIG_OUT of the delay circuit block 110 mixing the output signal OUT1 of the first delay circuit 120 with the output signal OUT2 of the second delay circuit 130 may be corrected by complementarily compensating the rising edge and the falling edge of the first and second delay circuits 120 and 130.

For example, the rising edge re_e of the even inverters IN2 and IN4 in the first delay circuit 120 may be compensated by a falling edge fe_e of the even inverters IN2 and IN4 in the second delay circuit 130 so that the delayed time al may be decreased to a delayed time a1/2.

FIG. 7 shows a graph illustrating a duty ratio transition, in accordance with example embodiments.

As indicated by FIG. 7 for a conventional delay circuit block, the NBTI stresses may be accumulated in delay elements so that the duty ratio gradually increases. By contrast, as indicated by FIG. 7 for the present delay circuit block 110, the second delay circuit 130 may be operated contrary to the first delay circuit 120 by enabling the compensation signal to offset the duty ratio.

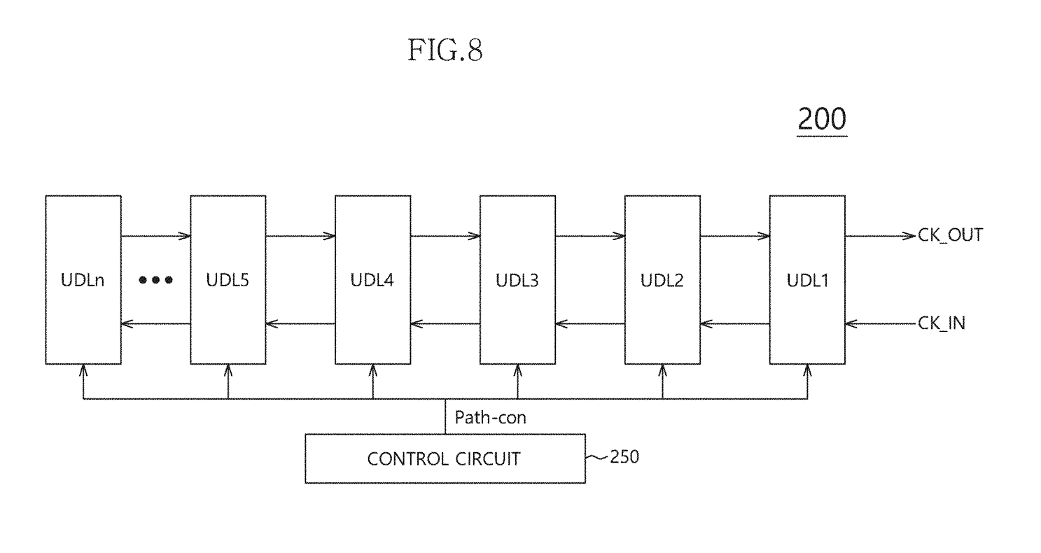

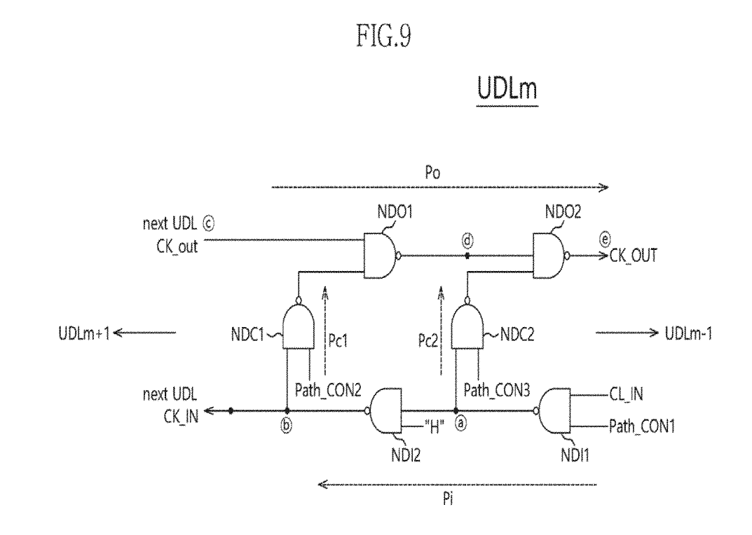

FIG. 8 shows a block diagram illustrating a delay circuit block 200, in accordance with example embodiments.

Referring to FIG. 8, the delay circuit block 200 of this example embodiment may include a plurality of unit delay lines UDL1˜UDLn and a control circuit 250.

Each of the unit delay lines UDL1˜UDLn may include a plurality of logic circuits. Further, the unit delay lines UDL1˜UDLn may have substantially the same configuration. The unit delay lines UDL1˜UDLn may be connected in series, to form the delay circuit block 200. The unit delay lines UDL1˜UDLn may be classified into first unit delay lines and second unit delay lines by a path control signal Path_CON provided from the control circuit 250. For example, the first unit delay lines are in the delay operating mode, such as for a burn-in test, and the second unit delay lines are in the standby mode of unit delay lines.

FIG. 9 shows a circuit diagram illustrating an m^{th} unit delay line UDLm of FIG. 8.

Referring to FIG. 9, the unit delay line UDLm may include first and second input NAND gates NDI1 and NDI2, first and second output NAND gates NDO1 and NDO2, and first and second via NAND gates NDC1 and NDC2.

The first input NAND gate NDI1 may receive an input signal CK_IN and a first path control signal Path_CON1 to perform a NAND operation. The second input NAND gate NDI2 may receive an output signal of the first input NAND gate NDI1 and a normally high voltage H to provide a next unit delay line ‘next UDL’ with a first output signal CK_OUT1 as an input clock CK_IN of the next unit delay line ‘next UDL’. An input path Pi may be formed by driving of the first and second input NAND gates NDI1 and NDI2. For example, the next unit delay line may be positioned to the left side of a selected unit delay line, and a previous unit delay line may be positioned to the right side of the selected unit delay line.

The first output NAND gate NDO1 may perform a NAND operation of an output signal CK_OUT of the next unit delay line ‘next UDL’ and an output signal of the first via NAND gate NDC1. The second output NAND gate NDO2 may perform a NAND operation of an output signal of the first output NAND gate NDO1 and an output signal of the second via NAND gate NDC2. An output path Po may be formed by driving of the first and second output NAND gates NDO1 and NDO2.

The first via NAND gate NDC1 may perform a NAND operation of an output signal of the second input NAND gate NDI2 and a second path control signal Path_CON2. A first via path Pc1 may be formed between the input path Pi and the output path Po based on a driving of the first via NAND gate NDC1.

The second via NAND gate NDC2 may perform a NAND operation of an output signal of the first input NAND gate NDI1 and a third path control signal Path_CON3. A second via path Pc2 may be formed between the first input NAND gate NDI1 and the second output NAND gate NDC2 based on a driving of the second via NAND gate NDC2. The first and second via paths Pc1 and Pc2 may be selectively formed for changing a path for transmitting a delayed clock path from the input path Pi to the output path Po, according to a delay amount.

Referring again to FIG. 8, the delay amount in the delay circuit block 200 included in the unit delay lines UDL1˜UDLn may be determined in accordance with a number of enabled unit delay lines UDL1˜UDLn. Enabling and disabling of unit delay lines UDL1˜UDLn may be determined by levels of the path control signals Path_CON1˜3. The disabled unit delay lines of the unit delay lines UDL1˜UDLn may be determined to be the standby mode of the unit delay lines. Thus, the path control signals Path_CON1˜3 of the unit delay lines UDL1˜UDLn may be independently controlled to generate various paths by the unit delay lines UDL1˜UDLn.

Each of the NAND gates, which constitutes the unit delay lines UDL1˜UDLn, may include two PMOS transistors and two NMOS transistors similarly to the inverter. Thus, when the delay operation is performed for a long time, the NBTI deterioration may be generated in the PHOS transistors of the NAND gate. As a result, the duty ratio of the delay circuit may be distorted.

According to example embodiments, the driving of the unit delay lines UDL1˜UDLn in the standby mode may be changed to control the path control signals Path_CON1˜3, thereby preventing the NBTI stresses from being accumulated.

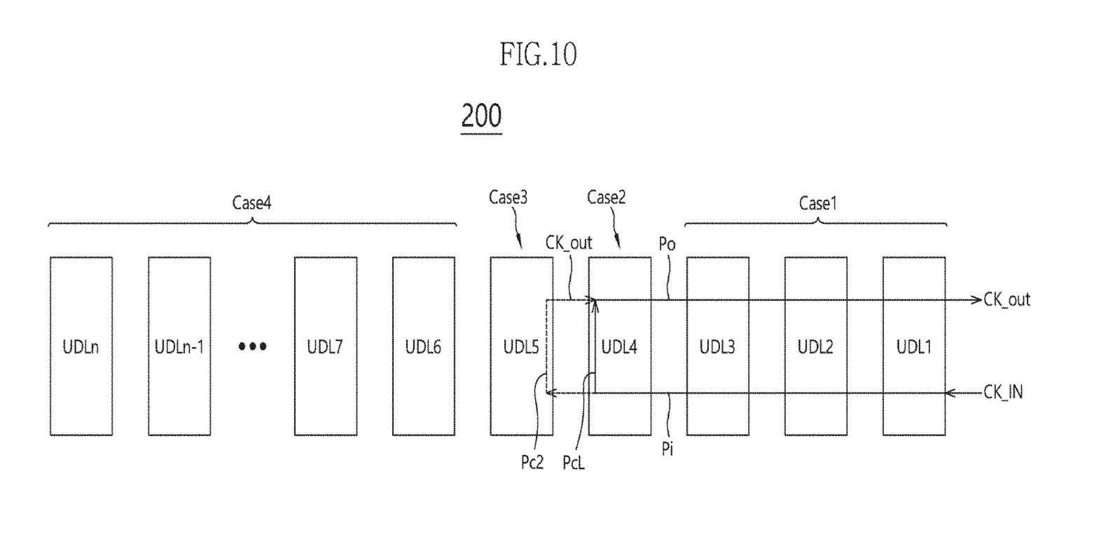

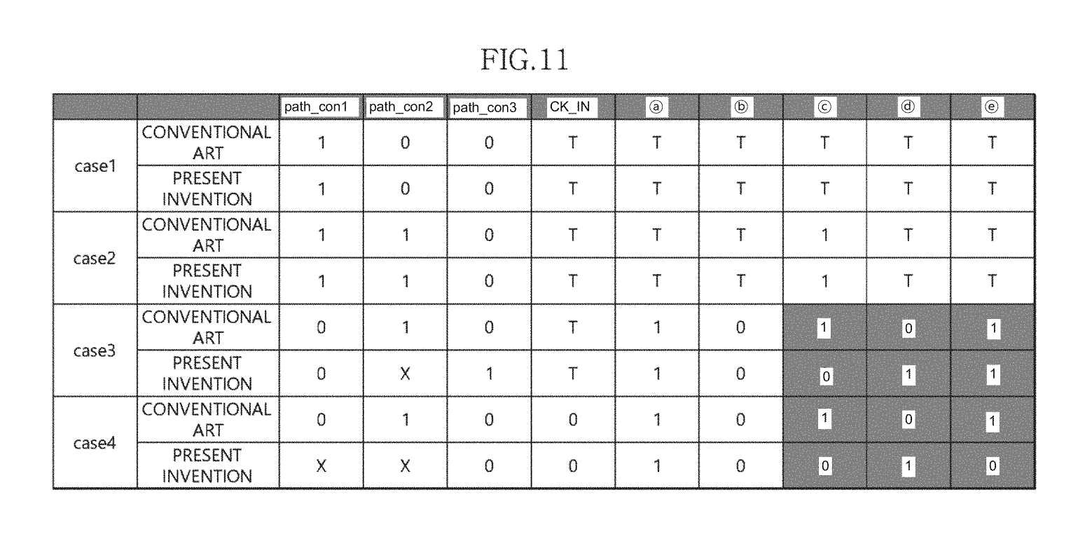

FIG. 10 shows a block diagram illustrating various operations of a plurality of unit delay lines, in accordance with example embodiments, and FIG. 11 shows a table tabulating application conditions of path control signals for operating the unit delay lines and signal levels of input/output nodes in accordance with the application conditions. In example embodiments, an output signal and an electric potential of an output node may be interpreted as a same meaning.

Referring to FIGS. 9 to 11, a first portion of the unit delay lines UDL1˜UDLn, for example, first to fourth unit delay lines UDL1˜UDLn, may be in the delay operating mode. A remaining portion of the unit delay lines UDL1˜UDLn, in this case the fifth to nth delay lines UDL5˜UDLn, may be in the standby mode. In the described embodiment, the first portion and the reaming portion together represent all of the unit delay lines UDL1˜UDLn.

The path control signals Path_CON1˜3 in accordance with Case 1 may be inputted into the first to third unit delay lines UDL1˜UDL3 for performing the delay operation in the delay operation mode, to generate the input path Pi and the output path Po in the first to third unit delay lines UDL1˜UDL3 without generating the first and second via paths Pc1 and Pc2. That is, the first path control signal Path_CON1 may be enabled to a high level and the second and third control signals Path_CON2 and Path_CON3 may be disabled to a low level. Further, an input clock T as an input signal CK_IN may be toggled. The input clock T may be transformed through output nodes \textcircled{a}, \textcircled{b}, \textcircled{c}, \textcircled{d}, and \textcircled{e} in the FIG. 9. The output node \textcircled{a} may be an output node of the first input NAND gate NDI1. The output node \textcircled{b} may be an output node of the second input NAND gate NDI2. The output node \textcircled{c} may be an input terminal on the output path Po, i.e., an output terminal of a next unit delay line next UDL CK_out. The output node \textcircled{d} may be an output node of the first output NAND gate NDO1. The output node may be an output node of a corresponding unit delay line UDL1˜UDL4 as well as an output node of the second output NAND gate NDO2. Thus, a low level signal may be applied to the even NAND gates NDI2 and NDO2 on the input/output path Pi and Po so that the even NAND gates NDI2 and NDO2 may receive the relatively more NBTI stresses during the delay operating mode.

The path control signals Path_CON1-3 in accordance with Case 2 (refer to FIG. 11) may be inputted into the fourth unit delay line UDL4. That is, the first and second path control signals Path_CON1 and Path_CON2 of the fourth unit delay line UDL4 may be enabled to a high level and the third path control signal Path_CON3 of the fourth unit delay line UDL4 may be disabled to a low level. Thus, a first via path Pc1 of the fourth unit delay line UDL4 may be formed between the input path Pi and the output path Po. Operations of the input/output paths Pi and Po in the fourth unit delay line UDL4 may be substantially the same as those of the first to third unit delay lines UDL1˜UDL3.

Although the fifth unit delay line UDL5 which is in the standby mode may not perform the delay operation, the path control signals Path._CON1˜3 in accordance with Case 3 (refer to FIG. 11) may be inputted into the fifth unit delay line UDL5 to provide the output path Po of the fourth unit delay line UDL4 with the input signal CK_out fedback from the fifth unit delay line UDL5. When the first path control signal Path_CON1 in the fifth unit delay line UDL5 may be disabled to a low level, the output node \textcircled{a} of the first input NAND gate NDI1 in the fifth unit delay line UDL5 may be continuously maintained at a high level. In order to prevent the generation of the first via path Pc1, the second path control signal Path_CON2 might not be inputted into the fifth delay line UDL5. The third path control signal Path_CON3 in the fifth unit delay line UDL5 may be enabled to a high level to generate a second via path Pct in the fifth unit delay line UDL5. Therefore, the second via NAND gate NDC2 may output a low level of a signal and the second output NAND gate NDO2 may output a high level of a signal regardless of an output signal of the first output NAND gate NDO1. The high level of the signal as the input signal CK_out may be inputted into the output path Po of the fourth unit delay line UDL4.

The sixth to nth unit delay lines UDL6˜UDLn may be in the standby mode. In order to provide the NAND gates, which might not be affected by the NBTI in the delay operating mode, with the NBTI influence, the path control signals Path_CON1˜3 in accordance with Case 4 may be inputted into the sixth to nth unit delay lines UDL6˜UDLn.

For example, the first and second path control signals Path_CON1˜2 corresponding to the Case 4 as shown in FIG. 11 might not be inputted into the sixth and nth unit delay lines UDL6˜UDLn. A low level of a signal as the input signal CK_IN may be inputted into the sixth unit delay line UDL6. Thus, each of the first input NAND gates NDI1 in the sixth to nth unit delay lines UDL6˜UDLn may be operated as an inverter. The low level of the signal may be inputted into the first input NAND gates NDI1 of the sixth to nth unit delay lines UDL6˜UDLn contrary to the first input NAND gates NDI1 of the unit delay lines UDL1˜UDL4 in the delay operating mode so that the first input NAND gate NDI1 of the sixth to nth unit delay lines UDL6˜UDLn may get the NBTI stress. The output nodes \textcircled{a} of the first input NAND gates NDI1 in the sixth to nth unit delay lines UDL6˜UDLn may have a high level of an electric potential.

A high level of input signals may be inputted into the second input NAND gates NDI2 in the sixth to nth unit delay lines UDL6˜UDLn so that the second input NAND gates NDI2 in the sixth to nth unit delay lines UDL6˜UDLn may output a low level of a signal.

In the sixth to nth unit delay lines UDL6˜UDLn, because the second path control signal Path_CON2 might not be inputted into the first via NAND gate NDC1, the first via NAND gate NDC1 may be just operated as an inverter. Because a low level of a signal may be inputted into the first via NAND gate NDC1 from the second input NAND gate NDI2, the first via NAND gate NDC1 may output a high level of a signal.

The first output NAND gates NDO1 of the sixth to nth unit delay lines UDL6˜UDLn may perform a NAND operation of the output signal of the next unit delay line next UDL CK_out on the output node \textcircled{c} and the output signal having a high level of the first via NAND gate NDC1. As shown in FIG. 10, the output signal of the next unit delay line next UDL CK_out on the output node \textcircled{c} may be set as a low level of a signal. Thus, the first output NAND gate NDO1 of the sixth to nth unit delay lines UDL6˜UDLn may get the NBTI stress in the standby mode contrary to the first output NAND gate NDO1 of the unit delay lines UDL1˜UDL4 in the delay operating mode and the first output NAND gate NDO1 of the sixth to nth unit delay lines UDL6˜UDLn may output a high level of a signal.

In the sixth to nth unit delay lines UDL6˜UDLn, the second output NAND gate NDO2 may perform a NAND operation of the output signal on the output node \textcircled{d} having a high level of the first output NAND gate NDO1 and the output signal of the second via NAND gate NDC2. The second via NAND gate NDC2 may perform a NAND operation of the output signal of the output node \textcircled{a} having a high level of the first input NAND gate NDI1 and the third path control signal Path_CON3 disabled to a low level, to output a high level of a signal. Therefore, the high level of the signals are inputted to all input terminals of the second output NAND gate NDO2. Thus, the second output NAND gates NDO2 may output a low level of a signal as the output signal CK_out. The output signal CK_out of a selected unit delay line among the sixth to nth unit delay lines UDL6˜UDLn may be provided to the output path Po in the previous unit delay line, which is shown positioned on the right side, as an input signal.

The low level of the signal may be inputted into the odd NAND gates NDI1 and NDO1 on the input/output paths Pi and Po of the unit delay lines UDL6˜UDLn in the standby mode. Thus, the odd NAND gates NDI1 and NDO1 of the unit delay lines UDL6˜UDLn in the standby mode may receive the relatively more NBTI stress contrary to the odd NAND gates NDI1 and NDO1 of the unit delay lines UDL1˜UDL3 in the delay operating mode.

When the unit delay lines UDL6˜UDLn in the standby mode are converted into the delay operating mode, the even NAND gates NDI2 and NDO2 may get the NBTI stress so that the duty ratio distortion caused by the complementary NBTI may be compensated.

In example embodiments, the odd NAND gates of the unit delay line in the operation mode may receive the high level of the signal. The even NAND gates of the unit delay line in the operation mode may receive the low level of the signal. The odd NAND gates of the unit delay line in the standby mode may receive the low level of the signal. The even NAND gates of the unit delay line in the standby mode may receive the high level of the signal. Alternatively, the above-mentioned effects may be achieved by a reverse condition of the condition indicated above.

In example embodiments, the inverter and the NAND gate may be exemplarily illustrated. Alternatively, combinations of a NOR gate, an inverter, a NAND gate, and a NOR gate may be used.

The above described embodiments of the present teachings are intended to illustrate and not to limit the present disclosure. Various alternate and/or equivalent embodiments are possible. The present disclosure is not limited by the embodiments described herein. Nor is the present disclosure limited to any specific type of semiconductor device. Other additions, subtractions, or modifications are obvious in view of the present disclosure and are intended to fall within the scope of the appended claims.

What is claimed is:

1. A semiconductor integrated circuit device comprising:
a first delay circuit comprising a first plurality of delay elements connected in series;
a second delay circuit comprising a second plurality of delay elements connected in series; and
a control circuit block connected between the first delay circuit and the second delay circuit, configured to receive an output signal of the first delay circuit, and to selectively output the output signal of the first delay circuit or an inverted output signal of the first delay circuit in response to a compensation signal.

2. The semiconductor integrated circuit device of claim 1, wherein the compensation signal is enabled in a standby mode.

3. The semiconductor integrated circuit device of claim 1, wherein the first and second pluralities of delay elements comprise an inverter.

4. The semiconductor integrated circuit device of claim 1, wherein the first and second pluralities of delay elements are each configured to perform a NAND logic operation.

5. The semiconductor integrated circuit device of claim 1, wherein the first and second pluralities of delay elements comprise a NAND logic gate.

6. The semiconductor integrated circuit device of claim 1, wherein the first and second pluralities of delay elements are each configured to perform an inversion operation.

7. A semiconductor integrated circuit device comprising:
a plurality of unit delay lines with each unit delay line including a plurality of delay elements connected in series,
wherein a first portion of the plurality of unit delay lines is in a delay operating mode based on a control signal, wherein a remaining portion of the plurality of unit delay lines is in a standby mode based on the control signal, and
wherein odd delay elements among the plurality of delay elements of the unit delay lines in the standby mode receive an input signal having a level contrary to a level of an input signal inputted into odd delay elements among the delay elements of the plurality of unit delay lines in the delay operating mode.

8. The semiconductor integrated circuit device of claim 7, wherein each of the unit delay lines of the plurality of unit delay lines comprises:
an input path including delay elements of the plurality of delay elements;
an output path including delay elements of the plurality of delay elements, the output path arranged opposite in direction with the input path; and
a via path connected between the input path and the output path, the via path including at least one delay element.

9. The semiconductor integrated circuit device of claim 8, wherein the control signal comprises:
a first control signal inputted into a delay element on the input path to generate the input path;
a second control signal for enabling a delay element between the input path and the output path; and
a third control signal for enabling a delay element between a first delay element on the input path and a last delay element on the output path under a condition that the input path is not generated.

10. The semiconductor integrated circuit device of claim 8, wherein even delay elements of the unit delay lines in the standby mode receive a signal having a low level when odd delay elements of the unit delay lines in the delay operating mode receive a signal having a low level,

11. The semiconductor integrated circuit device of claim 10, wherein the odd delay elements of the unit delay lines in the delay operating mode and the even delay elements of the unit delay lines in the standby mode form the input path and the output path.

12. The semiconductor integrated circuit device of claim 8, wherein odd delay elements of the unit delay lines in the standby mode receive a signal having a low level when even delay elements of the unit delay lines in the delay operating mode receive a signal having a low level.

13. The semiconductor integrated circuit device of claim 12, wherein the even delay elements of the unit delay lines in the delay operating mode and the odd delay elements of the unit delay lines in the standby mode form the input path and the output path.

14. The semiconductor integrated circuit device of claim 7, wherein the plurality of delay elements is configured to perform a NAND logic operation.

15. The semiconductor integrated circuit device of claim 7, wherein each delay element of the plurality of delay elements comprises at least one of an inverter and a NAND logic gate.

16. The semiconductor integrated circuit device of claim 7, wherein the plurality of delay elements is configured to perform an inversion operation.
